(19) United States
(12) Patent Application Publication
(10) Pub. No.: US 2017/0108297 A1
(43) Pub. Date: Apr. 20, 2017

(54) Fiber Thermal Interface

(71) Applicant: KULR TECHNOLOGY CORPORATION, Santa Clara, CA (US)

(72) Inventors: Timothy Ray Knowles, San Diego, CA (US); Michael Gerald Carpenter, San Diego, CA (US); Yoshio Robert Yamaki, San Diego, CA (US); Michael Mo, Saratoga, CA (US)

(21) Appl. No.: 15/298,209

(22) Filed: Oct. 19, 2016

Related U.S. Application Data
(60) Provisional application No. 62/243,624, filed on Oct. 19, 2015.

(51) Int. Cl. F28F 21/02; C23C 16/56; H01L 23/373; C23C 16/44

(52) U.S. Cl. CPC F28F 21/02; C23C 16/44; C23C 16/56; H01L 23/3733; F28F 2013/001

(57) ABSTRACT

A method for manufacturing a carbon fiber thermal interface, comprises the steps of: electroflocking carbon fibers onto a temporary substrate; coating parylene onto the electroflocked carbon fibers; and removing the temporary substrate. The carbon fiber thermal interface comprises: carbon fibers, wherein exposed areas of the carbon fibers have a layer of a coating agent, and wherein the carbon fibers are coupled together by the coating agent.

### CROSS REFERENCE

This application claims priority from a provisional patent application entitled “Fiber Thermal Interface” filed on Oct. 19, 2015 and having application No. 62/243,624. Said application is incorporated herein by reference.

### FIELD OF INVENTION

The present disclosure relates to a thermal interface material and, in particular, to a carbon fiber thermal interface material.

### BACKGROUND

Electronic microprocessors and other heat-generating electronic devices concentrate thermal energy in a very small space which requires thermal cooling to maintain acceptable operating conditions. The electronic devices transport the generated heat via heat sinks that use thermal interfaces (e.g., carbon fibers having a solid substrate, grease, phase change material, etc.) to transport the heat away from the electronic devices to the heat sink. Heat sinks have grown more efficient and better at removing heat, but the thermal interface materials used to transport heat to the heat sinks have not kept pace.

FIG. 1 illustrates a prior art apparatus of a thermal interface having carbon fibers and a substrate. A thermal interface 10 of the prior art comprises carbon fibers 12, a substrate 14 for holding the carbon fibers, and an adhesive layer 16. The thermal interface 10 is disposed across regions 18 and 20 for transferring heat energy from one region to the other region, and vice versa until a thermodynamic equilibrium is reached. The carbon fibers 12 have very high thermal conductivity. However, the substrate 14 and the adhesive layer 16 have low thermal conductivity, which lowers the overall performance of the thermal interface 10. Furthermore, the carbon fibers 12 are themselves problematic in that the carbon fibers 12 are also electrically conductive, which is typically an unwanted characteristic in electrical devices.

Therefore, there exist a need for new thermal interfaces that have high thermal conductivity, low thermal contact resistance, high electrical resistance, mechanical compliance, and long term reliability.

### SUMMARY OF INVENTION

Briefly, the present disclosure discloses a method for manufacturing a carbon fiber thermal interface, comprising the steps of: electroflocking carbon fibers onto a temporary substrate; coating parylene onto the electroflocked carbon fibers; and removing the temporary substrate. The carbon fiber thermal interface comprises: carbon fibers, wherein exposed areas of the carbon fibers have a layer of coating agent, and wherein the carbon fibers are coupled together by the coating agent. The first ends of the coated carbon fibers are connected to a heat source. The second ends of the coated carbon fibers are connected to a heat sink. The fibers can be trimmed to equal length using abrasives and/or machining. The fiber tips can be enlarged by adhering fine conductive powder of diamond or other thermally conductive material to increase the contact area at the surface and thereby improve heat transfer.

### DESCRIPTION OF THE DRAWINGS

The foregoing and other objects, aspects, and advantages of the present disclosure can be better understood from the following detailed description of the preferred embodiment of the disclosure when taken in conjunction with the accompanying drawings in which:

FIG. 1 illustrates a prior art apparatus of a thermal interface having carbon fibers and a substrate.

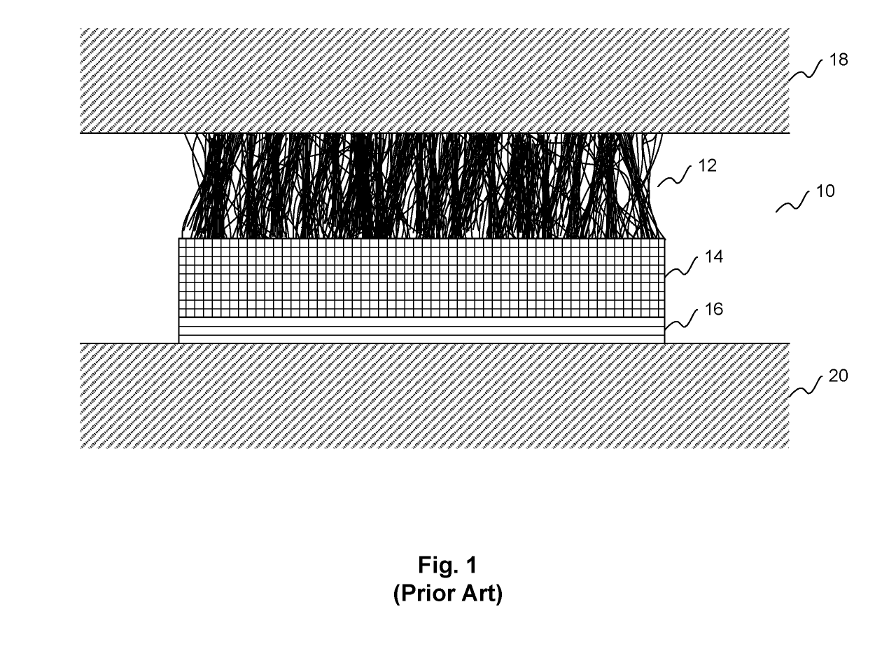

FIG. 2 illustrates a side view of a carbon fiber thermal interface of the present disclosure connected across thermal regions.

FIG. 3 illustrates a top view of a carbon fiber thermal interface of the present disclosure contacting a thermal region.

FIG. 4 illustrates a zoomed-in view of a few carbon fiber strands of a thermal interface of the present disclosure.

FIG. 5 illustrates a flow chart of a method for manufacturing a carbon fiber thermal interface.

FIG. 6 illustrates a top view of another embodiment of a carbon fiber thermal interface of the present disclosure.

FIG. 7 illustrates a zoomed-in view of a carbon fiber strand of a thermal interface of the present disclosure.

### DETAILED DESCRIPTION OF THE PREFERRED EMBODIMENTS

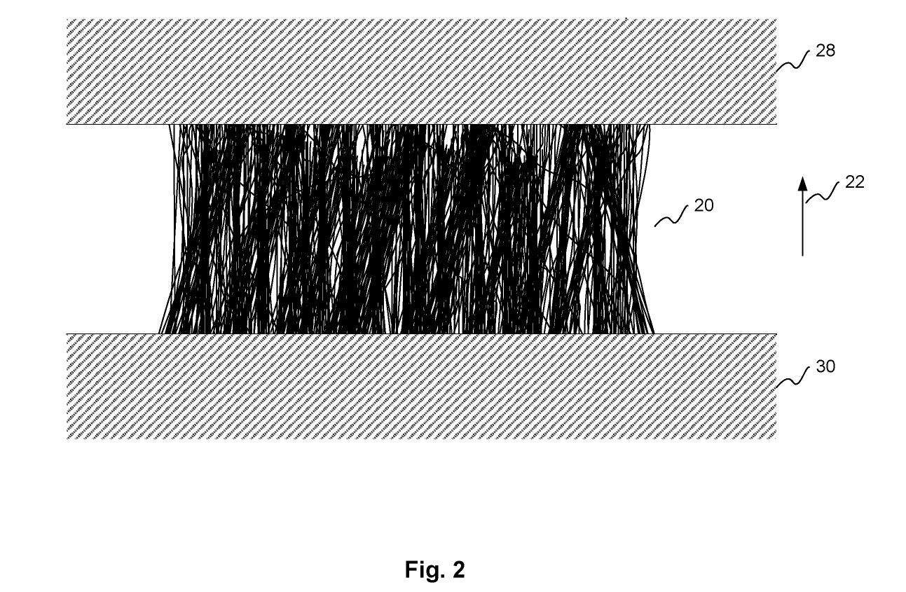

FIG. 2 illustrates a side view of a carbon fiber thermal interface of the present disclosure connected across thermal regions. Thermal regions can be any area, surface, or thing that receives, generates, or has heat energy, e.g., a heat sink, a central processing unit, a light-emitting-diode, a semi-conductor device, heat source, or other heating generating or receiving device. A carbon fiber thermal interface 20 of the present invention comprises carbon fibers that are held together by a coating agent that bonds adjacent carbon fibers together. Thus, the carbon fiber thermal interface 20 does not need a traditional substrate layer to hold the carbon fibers together at one end of the carbon fibers.

The carbon fibers of the thermal interface 20 can be substantially disposed in parallel along a first direction 22. The carbon fibers can be substantially disposed perpendicular to the regions 28 and 30. Alternatively, the carbon fibers can be substantially disposed at an angle to the regions 28 and 30. When the carbon fibers are disposed substantially at an angle to a region, the compliance and resilience of the carbon fibers may be increased as opposed to a substantially perpendicular configuration.

The ends of the carbon fibers can form two sides of the thermal interface 20. A first side of the thermal interface 20 can be disposed to contact a thermal region 28. A second side of the thermal interface 20 can be disposed to contact another thermal region 30. The coated carbon fibers are free to directly contact both regions 28 and 30. Thereby, heat transfer from one thermal region to another thermal region is maximized by having the coated carbon fibers contact both thermal regions 28 and 30. In other embodiments, the sides of the thermal interface 20 may have an adhesive deposition so that the thermal interface 20 can stick to either or both of the regions 28 and 30.

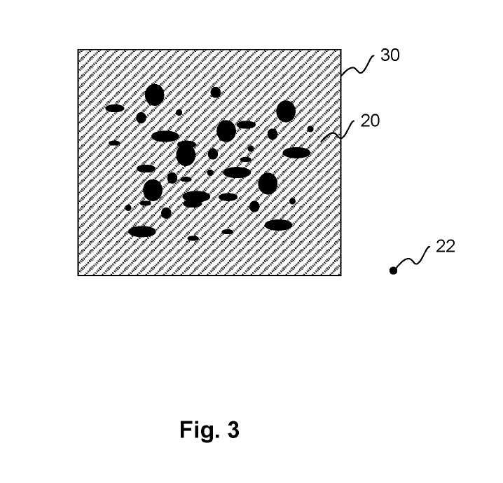

FIG. 3 illustrates a top view of a carbon fiber thermal interface of the present disclosure contacting a thermal region. A partial top view of the thermal interface 20 and the thermal region 30 show cross areas of the coated carbon fibers of the thermal interface 20 that contact the thermal region 30. In this top view, the direction 22 is perpendicular to the thermal region 30. The cross areas of the coated carbon fibers of the thermal interface 20 can have varying shapes since the carbon fibers may contact the region 30 at various angles, thereby having a variety of contact areas on the region 30.

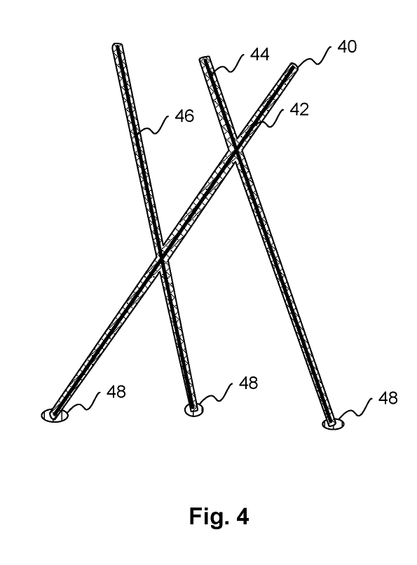

FIG. 4 illustrates a zoomed-in view of a few carbon fiber strands of a thermal interface of the present disclosure. A thermal interface of the present disclosure comprises carbon fibers bonded together using a coating agent. Coated carbon fibers 42-46 are examples of some of the carbon fibers of a thermal interface of the present disclosures.

The carbon fibers 42-46 have a coating agent 40 that coats the exposed surfaces of the carbon fibers 42-46. If the carbon fibers 42-46 have any exposed areas that are within a certain distance from each other, the coating agent may bridge that distance to connect those carbon fibers. Furthermore, if any areas of the carbon fibers 42-46 are in contact with each other, the coating agent can join the carbon fibers 42-46 at these areas by forming a layer of the coating agent around such areas.

The distance that allows for bridging can vary depending on one or more factors, including the width of the carbon fibers, the type of material of the coating agent, the method for coating, the amount of time of the coating, the temperature of the coating, and so forth. The carbon fibers 42-46 are electrical conductors. However, the coating agent 40 around the carbon fibers 42-46 can have high electrical resistance, which will effectively insulate the carbon fibers 42-46 from conducting electricity from one region to another region.

An adhesive coating 48 can be used to coat the ends of the carbon fibers 42-46. The adhesive coating 48 provides an adhesive surface so that the carbon fibers can be attached to a thermal region. The adhesive coating 48 can also serve to expand the area that the coated carbon fibers 42-46 contact the thermal region. The increased surface area allows for better thermal conductivity from the thermal region through the carbon fibers 42-46.

In alternative embodiments, the thermal interface can further comprise a veil layer, in which the carbon fibers are disposed through the veil layer. The carbon fibers can then be rigidized. Thus, a thermal interface can comprise: carbon fibers; and a veil layer, where the carbon fibers are disposed through the veil layer. The carbon fibers can also be canted. Furthermore, the carbon fibers are polished to a predefined length from the veil layer. The carbon fibers can have a first end and a second end. The veil layer also has a first side and a second side, where the first end of the carbon fibers is exposed through the first side of the veil layer and the second end of the carbon fibers is exposed through the second side of the veil layer. The veil layer can be made of a carbon veil. A thermally conductive powder can be disposed on tips of the carbon fibers at the first end and the second end of the carbon fibers. The thermally conductive powder can be one or more of the following: diamond, boron nitride, alumina, silver, graphite, silicon carbide, and/or any other thermally conductive powder.

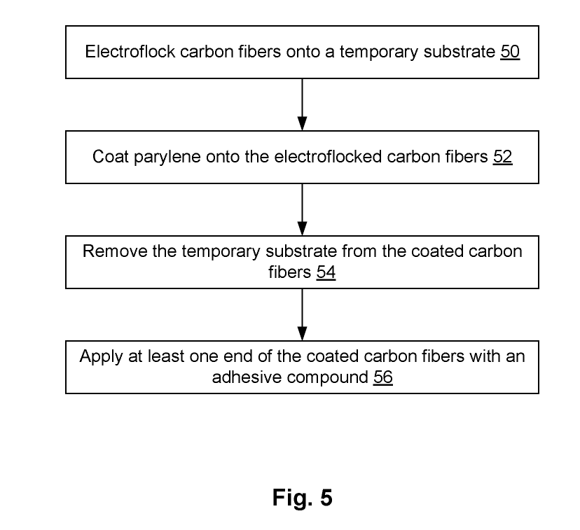

FIG. 5 illustrates a flow chart of a method for manufacturing a carbon fiber thermal interface. A thermal interface layer can be manufactured by electroflocking carbon fibers onto a temporary substrate 50. The electroflocked carbon fibers are then coated with a parylene (or other coating agent, including other forms of polymer) 52. The parylene can be coated onto the carbon fibers via chemical vapor deposition. It is understood that chemical vapor deposition is one of various methods for coating objects. Based on the present disclosure, a person having ordinary skill in the art can implement those other methods in conjunction with this step. The coated parylene can form a layer around the exposed surface area of the carbon fibers. The coated parylene layer also acts as a bonding agent keeping the carbon fibers together at various joints, where the carbon fibers are joined together by the parylene layer. Once the carbon fibers are held in place by the coated parylene layer, the temporary substrate can be removed from the coated carbon fibers 54. As an optional step, one side of the carbon fibers can be dipped in an adhesive compound 56. As another optional step, after the removing step, at least one end of the carbon fibers can be disposed with a thermally conductive powder.

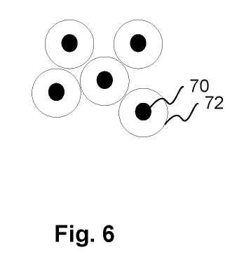

FIG. 6 illustrates a top view of another embodiment of a carbon fiber thermal interface of the present disclosure. Carbon fibers 70 of a carbon fiber thermal interface can be trimmed to have equal lengths using abrasives or machining. The electroflocked carbon fibers can typically have less than 10% surface coverage for an area. The fiber tips are enlarged by adhering fine conductive powder of diamond 72 (or other thermally conductive material) to increase the contact area at the surface and thereby improve heat transfer. The fiber tips are enlarged by adhering thermally conducting powder such as diamond or other conductive material. Enlarging the tips several times their diameter increases the contact area and the heat transfer of the interface.

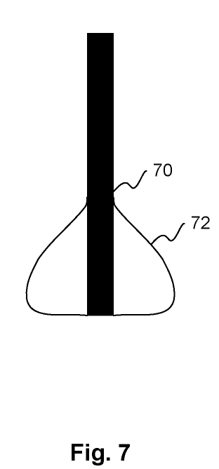

FIG. 7 illustrates a zoomed-in side view of a carbon fiber strand of a thermal interface of the present disclosure. The zoomed-in side view of the carbon fiber 70 has the conductive tip powder of diamond 72. In an example, the width of the carbon fiber 70 can be about five micrometer or other predefined width.

While the present invention has been described with reference to certain preferred embodiments or methods, it is to be understood that the present invention is not limited to such specific embodiments or methods. Rather, it is the inventors' contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

We claim:

1. A thermal interface, comprising:
carbon fibers,
wherein exposed areas of the carbon fibers have a layer of a coating agent, and
wherein the carbon fibers are coupled together by the coating agent.

2. The thermal interface of claim 1 wherein the coated carbon fibers are substantially aligned along a first direction and wherein each of the carbon fibers having a first end and a second end.

3. The thermal interface of claim 2 wherein the first ends of the coated carbon fibers are connectable to a heat source.

4. The thermal interface of claim 2 wherein the second ends of the coated carbon fibers are connectable to a heat sink.

5. The thermal interface of claim 1 wherein the carbon fibers have a first end and a second end and wherein a thermally conductive powder is disposed on the first end and the second end of the carbon fibers.

6. The thermal interface of claim 5 wherein the thermally conductive powder is one or more of the following: diamond, boron nitride, alumina, silver, graphite, silicon carbide, and any other thermally conductive powder.

7. A method for manufacturing a carbon fiber thermal interface, comprising the steps of:
electroflocking carbon fibers onto a temporary substrate;
coating parylene onto the electroflocked carbon fibers; and
removing the temporary substrate.

8. The method of claim 7 further comprising the step of, after the removing step, applying at least one end of the coated carbon fibers with an adhesive compound.

9. The method of claim 7 further comprising the step of, after the removing step, applying at least one end of the carbon fibers with a thermally conductive powder.

10. A thermal interface, comprising:
carbon fibers,
a carbon veil layer,
wherein the carbon fibers are disposed through the carbon veil layer,
wherein exposed areas of the carbon fibers have a layer of a coating agent, and
wherein the carbon fibers are coupled together by the coating agent.

11. The thermal interface of claim 10 wherein the coated carbon fibers are substantially aligned along a first direction and wherein each of the carbon fibers having a first end and a second end.

12. The thermal interface of claim 11 wherein the first ends of the coated carbon fibers are connectable to a heat source.

13. The thermal interface of claim 11 wherein the second ends of the coated carbon fibers are connectable to a heat sink.

14. The thermal interface of claim 10 wherein the carbon fibers have a first end and a second end and wherein a thermally conductive powder is disposed on the first end and the second end of the carbon fibers.

15. The thermal interface of claim 14 wherein the thermally conductive powder is one or more of the following: diamond, boron nitride, alumina, silver, graphite, silicon carbide, and any other thermally conductive powder.
